(19) United States
(12) Patent Application Publication
(10) Pub. No.: US 2016/0329223 A1
(43) Pub. Date: Nov. 10, 2016

(54) LIGHT IRRADIATION APPARATUS

(71) Applicant: USHIO DENKI KABUSHIKI KAISHA, Tokyo (JP)

(72) Inventor: Kenichi HIROSE, Tokyo (JP)

(73) Assignee: USHIO DENKI KABUSHIKI KAISHA, Tokyo (JP)

(21) Appl. No.: 15/108,063

(22) PCT Filed: Nov. 21, 2014
(86) PCT No.: PCT/JP2014/080915

§ 371 Date: Jun. 24, 2016

(30) Foreign Application Priority Data
Dec. 25, 2013 (JP) 2013-266564

(51) Int. Cl. H01L 21/67; B08B 5/00; B08B 7/00

(52) U.S. Cl. CPC H01L 21/67115; B08B 7/0057; B08B 5/00

(57) ABSTRACT

A light irradiation apparatus that can uniformly treat the entire to-be-treated surface of a to-be-treated subject having a light irradiation apparatus including: a treatment chamber in which a to-be-treated subject is disposed; an ultraviolet emitting lamp for emitting vacuum ultraviolet rays to the to-be-treated subject; and gas supply means for supplying a treatment gas containing a source of active species to the treatment chamber. A gas supply port for supplying the treatment gas to the treatment chamber and a gas discharge port for discharging the gas in the treatment chamber are provided on respective sides of a to-be-treated subject placement area in the treatment chamber so as to form a gas flow channel through which the treatment gas flows from the gas supply port toward the gas discharge port in the treatment chamber. How much of a gas amount at the gas supply port reaches the gas discharge port is controlled to be 60 to 95%.

### TECHNICAL FIELD

The present invention relates to a light irradiation apparatus for applying ultraviolet rays. More specifically, the present invention relates to a light irradiation apparatus that can be preferably applied to an optical ashing treatment of a resist in a manufacturing process of a semiconductor element or a liquid crystal panel, a process of removing a resist adhering to a patterned surface of a template in a nanoimprinting method, a dry cleaning treatment of a glass substrate for a liquid crystal panel or a silicon wafer, and a desmear treatment in a manufacturing process of a printed board.

### BACKGROUND ART

A manufacturing process of a semiconductor element or a liquid crystal panel, for example, involves an ashing treatment of a resist or a dry cleaning treatment on a glass substrate or a silicon wafer. Moreover, the nanoimprinting method involves a process of removing a resist adhering to a patterned surface of a template. Furthermore, in the manufacturing process of a printed board, a wiring board material is subjected to a desmear treatment or a surface roughening treatment of an insulating layer. As means for performing these treatments, a light irradiation apparatus that irradiates a to-be-irradiated subject with ultraviolet rays under an atmosphere of a treatment gas containing a source of active species such as an oxygen gas has been known (see Patent Literature 1, for example.).

In this light irradiation apparatus, the treatment gas around a to-be-treated subject is irradiated with vacuum ultraviolet rays. Consequently, the oxygen gas in the treatment gas is decomposed and oxygen radicals are thus generated. The contact of the oxygen radicals with the to-be-treated subject then causes the ashing of the to-be-treated subject, specifically, the ashing of a to-be-treated surface of the to-be-treated subject or foreign matter adhering to the to-be-treated subject.

In such light irradiation apparatus, as the ashing of the to-be-treated subject proceeds, the oxygen gas, which is the source of active species, is consumed and decomposed gas such as CO₂ is generated. This leads to a reduction in the concentration of the source of active species in the treatment gas around the to-be-treated subject and the generated amount of oxygen radicals is reduced due to the decomposed gas, such as CO₂, absorbing ultraviolet rays. For such a reason, a to-be-treated subject is typically irradiated with ultraviolet rays while supplying fresh treatment gas from one end side toward the other end side of the to-be-treated subject.

### CITATION LIST

### Patent Literature

Patent Literature 1: Japanese Patent Application Laid-Open No, 2002-075965

### SUMMARY OF INVENTION

### Technical Problem

However, it turns out that the above-described light irradiation apparatus has a problem as follows.

The decomposed gas, such as CO₂, generated by the ashing of the to-be-treated subject flows together with the treatment gas. Thus, the concentration of oxygen gas in a downstream region of a treatment gas flow becomes lower than the concentration of oxygen gas in an upstream region where fresh treatment gas is supplied. Moreover, the concentration of decomposed gas, such as CO₂, in the downstream region becomes higher than the concentration of decomposed gas in the upstream region. This makes the generated amount of oxygen radicals in the downstream region lower than the generated amount of oxygen radicals in the upstream region. Therefore, it is difficult to treat the entire to-be-treated surface of the to-be-treated subject uniformly.

The present invention has as its object the provision of a light irradiation apparatus that can treat the entire to-be-treated surface of a to-be-treated subject uniformly.

### Solution to Problem

According to the present invention, there is provided a light irradiation apparatus including: a treatment chamber in which a to-be-treated subject is disposed; an ultraviolet emitting lamp for emitting vacuum ultraviolet rays to the to-be-treated subject; and gas supply means for supplying a treatment gas containing a source of active species to the treatment chamber, wherein

a gas supply port for supplying the treatment gas to the treatment chamber and a gas discharge port for discharging the gas in the treatment chamber are provided on respective sides of a to-be-treated subject placement area in the treatment chamber so as to form a gas flow channel through which the treatment gas flows from the gas supply port toward the gas discharge port in the treatment chamber; and

how much of a gas amount at the gas supply port reaches the gas discharge port is controlled to be 60 to 95%.

The light irradiation apparatus of the present invention may preferably include a treatment gas supply amount adjusting means for setting a gas amount at the gas supply port, and

a flowmeter for measuring a gas amount at the gas discharge port.

Alternatively, the light irradiation apparatus may preferably include a treatment gas supply amount adjusting means for setting a gas amount at the gas supply port, and

a pressure gauge for measuring a gas pressure at the gas discharge port.

The light irradiation apparatus may preferably include a treatment gas supply amount adjusting means for setting a gas amount at the gas supply port, and

gas concentration measuring means for measuring a concentration of a specific gas component in the gas at the gas discharge port.

Moreover, gas leaking parts for leaking the gas from the treatment chamber may preferably be formed at positions on respective lateral sides of a treatment gas flowing direction in the gas flow channel.

Moreover, a gas recovery chamber for recovering the gas leaked from the treatment chamber may preferably be provided so as to surround the treatment chamber.

In such a light irradiation apparatus, an internal pressure of the gas recovery chamber may preferably be maintained at a pressure lower than an internal pressure of the treatment chamber during an operation thereof.

Moreover, the internal pressure of the gas recovery chamber may preferably be maintained at a pressure lower than an atmospheric pressure during the operation thereof.

### Advantageous Effects of the Invention

According to the light irradiation apparatus of the present invention, how much of the gas amount at the gas supply port reaches the gas discharge port is controlled to be 60 to 95%. This suppresses a reduction in the concentration of the source of active species and an increase in the concentration of the decomposed gas in the downstream region of the treatment gas flow channel. Thus, the entire to-be-treated surface of the to-be-treated subject can be treated uniformly.

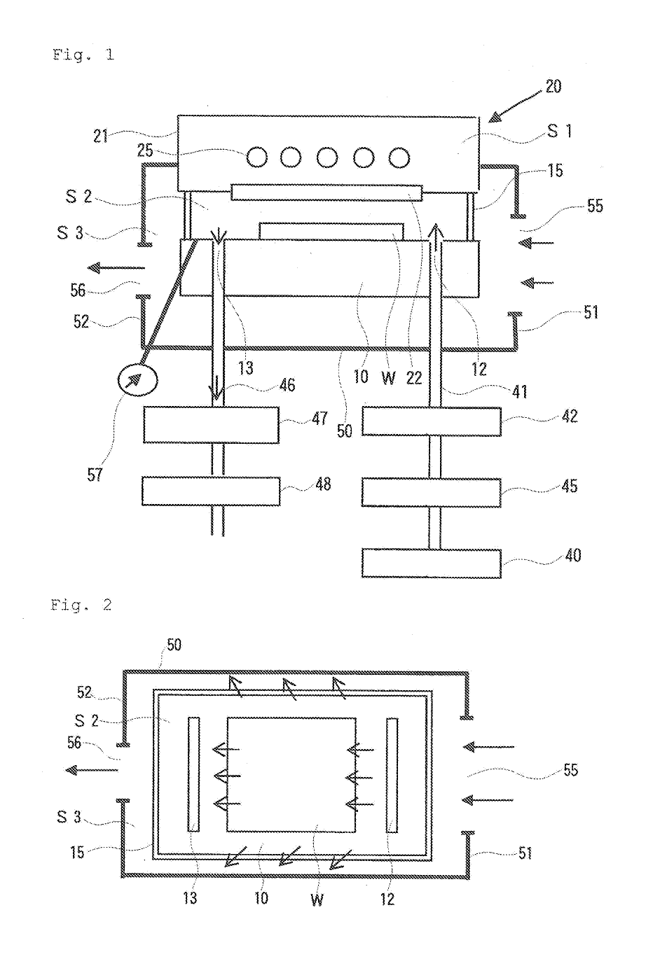

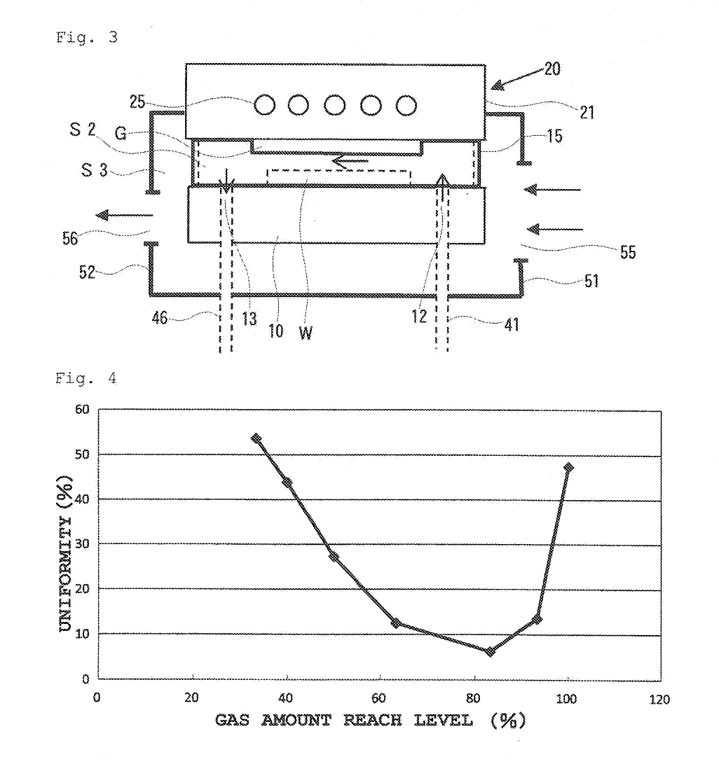

### BRIEF DESCRIPTION OF DRAWINGS

[FIG. 1] is an explanatory sectional view illustrating a general internal structure of an example of a light irradiation apparatus of the present invention.

[FIG. 2] is a plan view illustrating a state in which a light source unit has been removed from the light irradiation apparatus shown in FIG. 1.

[FIG. 3] is an explanatory view illustrating the shape of a wall of a treatment chamber forming member in the light irradiation apparatus shown in FIG. 1.

[FIG. 4] is a graph showing a relationship between how much of the amount of gas at a gas supply port reaches a gas discharge port and the uniformity of ashing treatment measured in an experimental example.

### DESCRIPTION OF EMBODIMENTS

An embodiment of a light irradiation apparatus of the present invention will be described below in detail.

FIG. 1 is an explanatory sectional view illustrating a general internal structure of an example of the light irradiation apparatus of the present invention. FIG. 2 is a plan view illustrating a state in which a light source unit has been removed from the light irradiation apparatus shown in FIG. 1.

This light irradiation apparatus includes a stage ID on which a to-be-treated subject W in a generally flat plate shape, for example, is placed. A light source unit 20 is disposed over stage 10 via a rectangular frame-shaped treatment chamber forming member 15 disposed along edge of the upper surface of the stage 10.

The light source unit 20 includes a generally rectangular parallelepiped box-shaped casing 21. A lower wall of the casing 21 is provided with a generally flat plate-shaped ultraviolet transmitting window 22 allowing for the transmission of vacuum ultraviolet rays. A sealed lamp accommodation chamber S1 is formed inside the casing 21. Moreover, a-treatment chamber S2 where the to-be-treated subject W is treated is formed between the ultraviolet transmitting window 22 and the stage 10 by being surrounded by the treatment chamber forming member 15.

In the light irradiation apparatus of the illustrated example, a gas recovery chamber S3 for recovering a gas leaked from the treatment chamber S2 is also provided so as to surround the treatment chamber S2. Specifically, the light irradiation apparatus includes a generally rectangular parallelpiped box-shaped gas recovery chamber forming member 50 having an opening in an upper wall thereof. The stage 10 and the treatment chamber forming member 15 are accommodated inside the gas recovery chamber forming member 50. The light source unit 20 is disposed over the treatment chamber forming member 15 with the casing 21 fitted in the opening of the gas recovery chamber forming member 50. The gas recovery chamber S3 is then formed by being surrounded by the inner surface of the gas recovery chamber forming member 50 and the outer surfaces of the stage 10 and the treatment chamber forming member 15.

In the lamp accommodation chamber S1, a plurality of rod-shaped ultraviolet emitting lamps 25 are disposed parallel to one another in the same horizontal plane. In the lamp accommodation chamber S1, a reflective mirror (not shown) is also provided above the ultraviolet emitting lamps 25. The casing 21 is also provided with gas purging means (not shown) for purging the inside of the lamp accommodation chamber S1 with an inert gas such as a nitrogen gas, for example.

Publicly known various lamps can be used as the ultraviolet emitting lamp 25 as long as the lamps can emit vacuum ultraviolet rays. Specifically, as examples of the ultraviolet emitting lamp 25, may be mentioned a low-pressure mercury lamp that emits vacuum ultraviolet rays of 185 nm, a xenon excimer lamp that emits vacuum ultraviolet rays with a center wavelength of 172 nm or a fluorescent excimer lamp in which a xenon gas is sealed in an arc tube and phosphor that emits vacuum ultraviolet rays of 190 nm, for example, is applied to the inner surface of the arc tube.

Any material having a transmissive property for vacuum ultraviolet rays emitted from the ultraviolet emitting lamps 25 and having a resistance property against vacuum ultraviolet rays and generated active species may be used as the material constituting the ultraviolet transmitting window 22. As an example of such a material, may be mentioned synthetic quartz glass.

In the stage 10, a gas supply port 12 for supplying a treatment gas to the treatment chamber S2 is formed on one side (the right side in the figure) of a to-be-treated subject placement area where the to-be-treated subject W is disposed so as to pass through the stage 10 in the thickness direction thereof. Also, a gas discharge port 13 for discharging a gas in the treatment chamber S2 is formed on the other side (the left side in the figure) of the to-be-treated subject placement area where the to-be-treated subject W is disposed so as to pass through the stage 10 in the thickness direction thereof. A gas flow channel through which the treatment gas flows from the gas supply port 12 toward the gas discharge port 13 is thus formed in the treatment chamber S2. The shape of the opening in each of the gas supply port 12 and the gas discharge port 13 is formed as a strip shape extending along the lamp axial direction of the ultraviolet emitting lamp 25.

A gas pipe 41 is connected to the gas supply port 12. Treatment gas supply means 40 for supplying the treatment gas to the treatment chamber S2 is connected to the gas pipe 41. The gas pipe 41 is provided with a flowmeter 42 for measuring the amount of gas at the gas supply port 12. The gas pipe 41 is also provided with treatment gas supply amount adjusting means 45 for setting the amount of gas at the gas supply port 12.

As the treatment gas supplied from the treatment gas supply means 40, a gas containing a source of active species is used. Any source of active species capable of generating active species by being irradiated with vacuum ultraviolet rays may be used as the source of active species contained in the treatment gas. As specific examples of such a source of active species, may be mentioned a source for generating oxygen radicals such as oxygen (O₂) or ozone (O₃), a source for generating OH radicals such as water vapor and a source for generating halogen radicals (for example, a source for generating fluorine radicals such as carbon tetrafluoride (CF₄), a source for generating chlorine radicals such as chlorine (Cl₂), a source for generating bromine radicals such as hydrogen bromide (HBr)). Among these, the source for generating oxygen radicals may preferably be used.

The concentration of the source of active species in the treatment gas is preferably not lower than 50% by volume, more preferably not lower than 70% by volume. The use of such a treatment gas causes a sufficient amount of active species to be generated when the treatment gas receives vacuum ultraviolet rays. Thus, the desired treatment can be performed reliably.

A gas pipe 46 is connected to the gas discharge port 13. The gas pipe 46 provided with an ozone concentration meter 47 for measuring the concentration of a specific gas. component in the gas at the gas discharge port 13, e.g., ozone and a flowmeter 48 for measuring the amount of gas at the gas discharge port 13.

Moreover, it is preferable that the stage 10 includes heating means (not shown) for heating the to-be-treated subject W. With such a structure, function caused by the active species can be promoted along with an increase in the temperature of a to-be-treated surface of the to-be-treated subject W. Thus, the treatment on the to-be-treated subject W can be performed efficiently. The flow of the treatment gas through the gas supply port 12 allows for the supply of the heated treatment gas to the treatment chamber S2. Thus, the flow of the treatment gas along the to-be-treated surface of the to-be-treated, subject W can also increase the temperature of the to-be-treated surface of the to-be-treated subject W. As a result, the above-described effect can be obtained more reliably.

For example, heating conditions by the heating means are conditions such that the temperature of the to-be-treated surface of the to-be-treated subject W is preferably not lower than 80° C. and not more than 340° C., more preferably not lower than 80° C. and not more than 200° C.

At positions on the both lateral sides of the flow direction of the treatment gas in the gas flow channel from the gas supply port 12 to the gas discharge port 13 in the treatment chamber S2, gas leaking parts for leaking the gas in the treatment chamber S2 from the treatment chamber S2 to the gas recovery chamber S3. Specifically, gaps G are formed, as shown in FIG. 3, between the upper ends side walls of the treatment chamber forming member 15 on the both sides (the upper side and the lower side in FIG. 2) of the gas flow channel and the lower surface of the casing 21 of the light source unit 20. The gaps G form the gas leaking parts.

Although the present embodiment describes that the gap C as shown in FIG. 3 is formed, the gap can take various forms as long as the gap can leak the gas. For example, a small gap may be formed between the lower surface of the casing 21 of the light source unit 20 and the treatment chamber forming member 15 or between the ultraviolet transmitting window 22 and the treatment chamber forming member 15.

An air introducing port 55 for introducing air into the gas recovery chamber S3 is formed in one side wall 51 of the gas recovery chamber forming member 50. Moreover, a gas suction port 56 for auctioning the gas in the gas recovery chamber S3 is formed in the other side wall 52 of the gas recovery chamber forming member 50. The gas suction port 56 is connected to depressurization means (not shown) for depressurizing the gas recovery chamber S3. The inside of the gas recovery chamber S3 can be kept in a depressurized sate by discharging the gas in the gas recovery chamber S3 via the depressurization means such as a blower, for example.

The light irradiation apparatus is also provided with a differential pressure gauge 57 for measuring a difference between the internal pressure of the treatment chamber S2 and the internal pressure of the gas recovery chamber S3.

In the light irradiation apparatus of the present invention, the to-be-treated subject W is irradiated with ultraviolet rays in the following manner.

First, the to-be-treated subject W is placed in the to-be-treated subject placement area on the stage 10. The to-be-treated subject W is heated, if necessary, by the heating means provided in the stage 10.

Next, an inert gas is supplied to the lamp accommodation chamber S1 by the gas purging means. Therefore, the inert gas purges the inside of the lamp accommodation chamber S1.

Also, a treatment gas is supplied to the treatment chamber S2 via the gas supply port 12 by the treatment gas supply means 40. The treatment gas supplied to the treatment chamber S2 is discharged from the treatment chamber S2 via the gas discharge port 13. The treatment gas thus flows along the gas flow channel from the gas supply port 12 toward the gas discharge port 13 in the treatment chamber S2. At this time, part of the treatment gas supplied from the gas supply port 12 to the treatment chamber S2 leaks into the gas recovery chamber S3 from the gas leaking parts.

After that, the ultraviolet emitting lamps 25 in the light source unit 20 are lit. Vacuum ultraviolet rays from the ultraviolet emitting lamps 25 are then projected on the to-be-treated subject W via the ultraviolet transmitting window 22 as well as the treatment gas flowing through the gap between the ultraviolet transmitting window 22 and the to-be-treated subject W. This causes the source of active species contained in the treatment gas to be decomposed, thereby generating active species. As a result, the desired treatment is performed on the to-be-treated subject W by the vacuum ultraviolet rays having reached the to-be-treated surface of the to-be-treated subject W and the active species generated by the vacuum ultraviolet rays.

In the above-described structure, how much of the amount of gas at the gas supply port 12 reaches the gas discharge port 13 (hereinafter, it is referred to as a “gas amount reach level.”) is controlled to be 60 to 95%, preferably 63 to 93%. The gas amount reach level represents a percentage of the amount of gas at the gas discharge port 13 with respect to the amount of gas at the gas supply port 12. In the light irradiation apparatus of the illustrated example, the gas amount reach level can be checked from the amount of gas measured by the flowmeter 42 and the amount of gas measured by the flowmeter 48. When the gas amount reach level changes, the concentration of ozone, which is a specific gas component in the gas at the gas discharge port 13, changes. Therefore, if a calibration curve between a gas amount reach level and a concentration of ozone in the gas at the gas discharge port 13, for example, is created in advance, the gas amount reach level can be checked also from the concentration of ozone measured by the ozone concentration meter 47.

When the gas amount reach level is lower than 60%, the treatment gas is less likely to flow from an upstream region to a downstream region in the gas flow channel. Thus, the decomposed gas generated in the downstream region tends to stay there. This increases the concentration of the decomposed gas in the downstream region in the gas flow channel. When the gas amount reach level is greater than 95%, on the other hand, all or large part of the decomposed gas generated in the upstream region in the gas flow channel flows to the downstream region. This increases the concentration of the decomposed gas in the downstream region in the gas flow channel.

The gas amount reach level can be adjusted by changing the size of the gas leaking parts, specifically, the size of the gaps between the upper ends of the side walls of the treatment chamber forming member 15 on the both sides of the gas flow channel and the lower surface of the casing 21 of the light source unit 20.

Moreover, when the separation distance between the ultraviolet transmitting window 22 and the to-be-treated subject W is set to be 0.1 to 3 mm, the gas amount at the gas supply port 12 is adjusted so that the flow velocity of the treatment gas over the to-be-treated subject W is preferably 1 to 100 mm/sec, more preferably 2 to 50 mm/sec.

The flow velocity of the treatment gas over the to-be-treated subject W (the flow velocity of the treatment gas flowing through the gap between the ultraviolet transmitting window 22 and the to -be -treated subject W) can be obtained as follows.

A sectional area C of a cross section of a gas flow space in the treatment chamber S2 perpendicular to the flow direction of the treatment gas is the sum of a sectional area C1 of a cross section of a treatment gas flow space over the to-be-treated subject W (the gap between the ultraviolet transmitting window 22 and the to-be-treated subject W) perpendicular to the flow direction of the treatment gas and a sectional area C2 of a cross section of a treatment gas flow space around the to-be-treated subject W perpendicular to the flow direction of the treatment gas (C=C1+C2).

When the ratio of the sectional area C2 to the sectional area C1 (C2/C1=100) is not more than 2% or when the gas amount reach level is not lower than 70%, the flow velocity of the treatment gas can be calculated (approximated) by the following formula (1).

V=Q/C Formula (1)

provided that V is the flow velocity (unit: m/s) of the treatment gas over the to-be-treated subject W; Q is the flow rate (unit: mm³/sec) of the treatment gas flowing through the gas discharge port 13; and C is the sectional area (unit: mm²) of the cross section of the gas flow space in the treatment chamber S2 perpendicular to the flow direction of the treatment gas. Here, the flow rate of the treatment gas flowing through the gas discharge port 13 is a value obtained by multiplying the flow rate of the treatment gas supplied to the treatment chamber S2 by the gas amount reach level.

When the ratio of the sectional area C2 to the sectional area C1 (C2/C1×100) is more than 2% or when the gas amount reach level is lower than 70%, the flow velocity of the treatment gas can be calculated by performing condition setting as will be described below to analyze the behavior of the treatment gas in the treatment chamber S2 using, for example, a general-purpose thermo-fluid analysis software “ANSYS Fluent” (manufactured by ANSYS, Inc.).

Flow channel model: the flow channel model of the treatment gas is set on the basis of the shapes, arrangement, and the like of the stage 10 the to-be-treated subject W, the ultraviolet transmitting window 22, the gap between the ultraviolet transmitting window 22, and the subject W, a sealant, and the like.

Physical property condition setting of treatment gas: the density and viscosity coefficient of the treatment gas (if the treatment gas is an oxygen gas, for example, the density is 1.2999 kg/m³ and the viscosity coefficient is 1.92×10⁻⁵ Pa·s) are inputted.

Boundary condition setting: the inlet of the treatment gas (the opening of the gas supply port 12) is set in (m/s). The outlet of the treatment gas (the opening of the gas discharge port 13) is an atmospheric pressure surface.

Moreover, in order to check the uniformity of the flow velocity of the treatment gas, steady calculation is performed. Moreover, the flow velocity of the treatment gas is obtained (approximated) as an average value in the upper space of the to-be-treated surface of the to-be-treated subject W.

Moreover, during the operation of the light irradiation apparatus, it is preferable that the internal pressure of the gas recovery chamber S3 is maintained at a pressure lower than the internal pressure of the treatment chamber S2. This can cause the gas in the treatment chamber S2 to be reliably leaked into the gas recovery chamber S3 via the gas leaking part. Specifically, the difference between the internal pressure of the treatment chamber S2 and the internal pressure of the gas recovery chamber S3 is not lower than 50 Pa, preferably 100 to 500 Pa, in particular.

Moreover, during the operation of the light irradiation apparatus, it is preferable that the internal pressure of the gas recovery chamber S3 is maintained at a pressure lower than the atmospheric pressure. This can prevent the treatment gas recovered in the gas recovery chamber S3 from flowing out to the outside. Moreover, harmful gas or the like in the treatment gas can be easily treated since the recovered treatment gas is diluted due to the introduction of air into the gas recovery chamber S3 from the air introducing port 55. Specifically, the difference between the internal pressure of the gas recovery chamber S3 and the atmospheric pressure is not lower than 30 Pa, preferably 30 to 1,000 Pa, in particular.

Moreover, during the operation of the light irradiation apparatus, it is preferable that the internal pressure of the treatment chamber S2 is maintained at a pressure higher than the internal pressure of the lamp accommodation chamber S1. This can prevent the gas in the lamp accommodation chamber S1 from flowing into the treatment chamber S2. Specifically, the difference between the internal pressure of the treatment chamber S2 and the internal pressure of the lamp accommodation chamber S1 is not lower than 30 Pa, preferably 30 to 1,000 Pa, in particular.

According to the light irradiation apparatus of the present invention, how much of the amount of gas at the gas supply port 12 reaches the gas discharge port 13 is controlled to be 60 to 95%. This suppresses a reduction in the concentration of the source of active species and an increase in the concentration of the decomposed gas in the downstream region of the treatment gas flow channel. Thus, the entire to-be-treated surface of the to-be-treated subject W can be treated uniformly.

The light irradiation apparatus of the present invention is not limited to the above-described embodiment and various modifications can be made thereto.

For example, a pressure gauge for measuring a gas pressure at the gas discharge port 13 may be provided in place of the ozone concentration meter 47. When the gas amount reach level changes, the gas pressure at the gas discharge port changes. Therefore, if a calibration curve between a gas amount reach level and a gas pressure at the gas discharge port, for example, is created in advance, change in the gas amount reach level can be checked from the gas pressure measured by the pressure gauge.

### EXPERIMENTAL EXAMPLE 1

An experimental example performed for, confirming the effect of the present invention will be described below.

A light irradiation apparatus for experiments was manufactured on the basis of the following specification in accordance with the structures shown in FIGS. 1 to 3.

### Stage (10):

Size: 650 mm×560 mm×20 mm
Material: aluminum
Opening size of gas supply port (12): 500 mm×5 mm
Opening size of gas discharge port (13): 500 mm×10 mm

### Ultraviolet Emitting Lamps (25):

Diameter of ultraviolet emitting lamp (25): 40 mm
Emission length of ultraviolet emitting lamp (25): 700 mm
Input power: 500 W
The number of ultraviolet emitting lamps (25): five

### Ultraviolet Transmitting Window (22):

Size: 550 mm×550 mm×5 mm
Material: synthetic quartz glass

### Treatment Chamber (S2):

Size: 600 mm×504 mm×0.5 mm

### Gas Recovery Chamber (S3):

Size: 800 mm×700 mm×40 mm

The light irradiation apparatus was operated under the following conditions and gauge pressures (positive pressures) and ozone concentrations at the gas discharge port were measured. The results are shown in Table 1.

### Operation Conditions:

Treatment gas: 100% oxygen concentration
Gas amount at gas supply port: 1 L/min
Gas amount at gas discharge port: those shown by Table 1.
Gauge pressure (negative pressure) in gas recovery chamber: 70 Pa

TABLE 1

| GAS AMOUNT | | GAS | | | GAUGE |
|---|---|---|---|---|---|
| (L/min) | | AMOUNT | OZONE | | PRESSURE |
| GAS | GAS | REACH | CONCEN- | | AT GAS |
| SUPPLY | DISCHARGE | LEVEL | TRATION | | DISCHARGE |
| PORT | PORT | (%) | (%) | (g/m³) | PORT (Pa) |
| 1 | 1 | 100 | 3.1 | 62 | 200 |
| 1 | 0.92 | 92 | 1.55 | 31 | 190 |
| 1 | 0.65 | 65 | 0.6 | 12 | 120 |

It can be seen from the results in Table 1 that a change in the gas amount reach level leads to changes in the gas pressure and the ozone concentration at the gas discharge port Therefore, the change in the gas amount reach level can be checked by the gas pressure or the ozone concentration at the gas discharge port.

### EXPERIMENTAL EXAMPLE 2

With the light irradiation apparatus manufactured in Experimental example 1, desmear treatment was performed on the following printed circuit board material under the following conditions.

### Printed Circuit Board Material:

Structure: the structure is made by layering an insulating layer on copper foil and forming via holes in the insulating layer.
Planar size: 500 mm×500 mm×0.5 mm
Thickness of copper foil: 35 μm
Thickness of insulating layer: 30 μm
Diameter of via hole: 50 μm

### Conditions:

Treatment gas: 100% oxygen concentration
Distance between ultraviolet transmitting window and printed circuit board: 0.5 mm
Temperature of stage: 120° C.
Gas amount at gas supply port: 0.3 L/min
Gas amount at gas discharge port: those shown by Table 1.
Gauge pressure (positive pressure) at gas discharge port: those shown by Table 2.
Irradiation time of vacuum ultraviolet rays: for 200 seconds
Gauge pressure (negative pressure) in gas recovery chamber: 70 Pa

After the light irradiation treatment was performed, elemental analyses by energy dispersive x-ray spectrometry (EDX) were conducted about the bottoms (copper foil) of the via hole formed in the printed circuit board material at a position distant from the upstream end of the treatment gas flow channel by 30 mm, the via hole formed at the middle position and the via hole formed at a position distant from the downstream end by 30 mm to determine ratios between carbon and copper (hereinafter, these are referred to as “C/Cu ratios.”) Note that the C/Cu ratios about the bottoms of the respective via holes in the printed circuit board material before the treatment were all 0.80.

Thereafter, from the obtained C/Cu ratios, the uniformity of the desmear treatment was obtained by the following formula. The results are shown in Table 2 and FIG. 4.

Uniformity=(maximum C/Cu ratio−minimum C/Cu ratio)/(maximum C/Cu ratio+minimum C/Cu ratio)×100[%]

TABLE 2

| | | GAS | | | | | GAUGE |
|---|---|---|---|---|---|---|---|
| GAS AMOUNT (L/min) | | AMOUNT | | | | | PRESSURE |
| GAS | GAS | REACH | C/Cu RATIO | | | | AT GAS |
| SUPPLY | DISCHARGE | LEVEL | UP | | DOWN | UNIFORMITY | DISCHARGE |
| PORT | PORT | (%) | STREAM | MIDDLE | STREAM | (%) | PORT (Pa) |
| 0.3 | 0.1 | 33 | 0.16 | 0.41 | 0.53 | 54 | 22 |
| 0.3 | 0.12 | 40 | 0.16 | 0.36 | 0.41 | 44 | 24 |
| 0.3 | 0.15 | 50 | 0.16 | 0.23 | 0.28 | 27 | 28 |
| 0.3 | 0.19 | 63 | 0.14 | 0.16 | 0.18 | 13 | 34 |
| 0.3 | 0.25 | 83 | 0.15 | 0.16 | 0.17 | 6 | 41 |
| 0.3 | 0.28 | 93 | 0.16 | 0.18 | 0.21 | 14 | 46 |
| 0.3 | 0.3 | 100 | 0.15 | 0.31 | 0.42 | 47 | 48 |

As shown in Table 2 and FIG. 4, it was confirmed that favorable uniformity (uniformity of not more than 20%) about the desmear treatment can be obtained when the gas amount reach level is 60 to 95%.

### REFERENCE SIGNS LIST

10 stage
12 gas supply port
13 gas discharge port
15 treatment chamber forming member
20 light source unit
21 casing
22 ultraviolet transmitting window
25 ultraviolet emitting lamp
40 treatment gas supply means
41 gas pipe
42 flowmeter
45 treatment gas supply amount adjusting means
46 gas pipe
47 ozone concentration meter
48 flowmeter
50 gas recovery chamber forming member
51 one side wall
52 the other side wall
55 air introducing port
56 gas suction port
57 differential pressure gauge
G gap
W to-be-treated subject
S1 lamp accommodation chamber
S2 treatment chamber
S3 gas recovery chamber

1. A light irradiation apparatus comprising: a treatment chamber in which a to-be-treated subject is disposed; an ultraviolet emitting lamp for emitting vacuum ultraviolet rays to the to-be-treated subject; and gas supply means for supplying a treatment gas containing a source of active species to the treatment chamber, wherein
a gas supply port for supplying the treatment gas to the treatment chamber and a gas discharge port for discharging the gas in the treatment chamber are provided on respective sides of a to-be-treated subject placement
area in the treatment chamber so as to form a gas flow channel through which the treatment gas flows from the gas supply port toward the gas discharge port in the treatment chamber;
the gas leaking parts for leaking the gas from the treatment chamber is formed at the gas flow channel; and
how much of a gas amount at the gas supply port reaches the gas discharge port is controlled to be 60 to 95%.

2. The light irradiation apparatus according to claim 1, comprising:
a treatment gas supply amount adjusting means for setting a gas amount at the gas supply port, and
a flowmeter for measuring a gas amount at the gas discharge port.

3. The light irradiation apparatus according to claim 1, comprising:
a treatment gas supply amount adjusting means for setting a gas amount at the gas supply port, and
a pressure gauge for measuring a gas pressure at the gas discharge port.

4. The light irradiation apparatus according to claim 1, comprising:
a treatment gas supply amount adjusting means for setting a gas amount at the gas supply port, and
gas concentration measuring means for measuring a concentration of a specific gas component in the gas at the gas discharge port.

5. The light irradiation apparatus according to claim 1, wherein the gas leaking arts are formed at positions on respective lateral sides of a treatment gas flowing direction in the gas flow channel.

6. The light irradiation apparatus according to claim 1, wherein a gas recovery chamber for recovering the gas leaked from the treatment chamber is provided so as to surround the treatment chamber.

7. The light irradiation apparatus according to claim 6, wherein an internal pressure of the gas recovery chamber is maintained at a pressure lower than an internal pressure of the treatment chamber during an operation thereof.

8. The light irradiation apparatus according to claim 7, wherein the internal pressure of the gas recovery chamber is maintained at a pressure lower than an atmospheric pressure during the operation thereof.
